(19) United States
(12) Patent Application Publication
(10) Pub. No.: US 2004/0036148 A1
(43) Pub. Date: Feb. 26, 2004

(54) Electric component, method for the production thereof, and its use

(76) Inventors: Christian Block, Stainz (DE); Roman Grebien, Elbiswald (AT); Martin Mayer, Koflach (AT); Klaus Unegg, Deutschlandsberg (AT)

Correspondence Address: FISH & RICHARDSON PC, 225 FRANKLIN ST, BOSTON, MA, 02110, US

(21) Appl. No.: 10/363,084

(22) PCT Filed: Jul. 3, 2001
(86) PCT No.: PCT/DE01/02453

(30) Foreign Application Priority Data
Aug. 28, 2000 (DE) 100 42 229.2

(51) Int. Cl. H01L 29/40; H01L 23/04

(52) U.S. Cl. 257/621; 257/698

(57) ABSTRACT

The invention relates to an electric component having a main body (1), which features an upper side and a lower side and consists at least partially of a dielectric, on the upper side of which a raised or recessed limiting structure (2) borders an upper contact surface (3) which is covered by an upper contact layer (4) whose lower side features two lower contact surfaces (5, 6) insulated from one another, each of which is covered with a lower contact layer (7, 8), and in which one of the lower contact layers (5, 6) is connected in electrically conductive fashion to the upper contact layer (4) by a connecting element (9) passing through the interior of the main body (1). In addition, the invention relates to a method for manufacturing the component as well as its use. The advantage of the component according to the invention is that the upper contact surface (3) can be easily applied at a defined size by means of silk screening or vacuum metallization. As a result, antennas with defined properties, such as frequency position and input impedance, can be easily manufactured.

The invention relates to an electric component having a main body, which features an upper side and a lower side and comprises a dielectric, on the upper side of which an upper contact layer is arranged and on the lower side of which a lower contact layer is arranged. In addition, the invention relates to a method for manufacturing the electric component. Furthermore, the invention relates to the use of the electric component.

Electric components of the type noted above are known, whose main bodies consist partially of barium titanate and which are used as patch antennas for radio signals. The upper contact layer is contacted at a feed point at which the radio signal is input into the main body. The dimensions of the upper contact layer and its position relative to the feed point determine the electrical properties of the antenna, such as frequency length, input impedance, and irradiation characteristics.

In prior art antennas, an upper contact surface is deposited onto a flat upper side of a main body and, in a subsequent etching process, is structured so that the upper contact layer has desired dimensions. In the same manner, the lower contact surface, which serves as a ground surface, is produced by depositing a metallized coating onto a flat lower side of the main body. The components are mounted onto a printed circuit board with the lower side facing the printed circuit board. The bonding of the upper contact layer with the printed circuit board is achieved via a contact pin progressing outside the main body, with the contact point of the contact pin simultaneously establishing the feed point on the upper contact layer.

The precipitation of the upper contact surface can also be accomplished by applying a silver silk screening metallized coating, thereby eliminating the need for an additional structuring process.

A disadvantage of prior art patch antennas is that substantial expenditure is necessary to set the exact dimensions of the upper contact layer, since structuring processes must be applied in addition to the precipitation of a metal coating. The structuring processes are normally performed via photolithography and masks used therewith. As both the dimensions of the upper contact layer and its position relative to the main body and/or the feed point are important, the antennas must be very precisely positioned relative to a photolithography mask.

Another disadvantage of prior art antennas is that an additional contact pin, which must be bonded in an additional process, is needed to bond the upper contact surface to the printed circuit board. Soldering of a contact pin is disadvantageous in that steps must be taken to ensure that the position of the feed point relative to the upper contact layer is precisely maintained.

The object of the present invention, therefore, is to provide an electric component that can be used as an antenna. A further object is that the manufacture of an upper contact layer with precisely defined dimensions and/or the manufacture of a precisely defined feed point can be achieved without substantial cost.

According to the invention, this object is achieved with an electric component according to claim 1. Additional embodiments of the invention, a method for manufacturing the component, and the use of the component may be derived from the remaining claims.

The invention specifies an electric component that features a main body with an upper side and a lower side that at least partially comprises a dielectric. On the upper side of the main body, a raised or recessed limiting structure is provided which borders an upper contact surface. The upper contact surface is covered with an upper contact layer. On the lower side, the main body features two lower contact surfaces that are insulated from one another, each of which is covered with a lower contact layer.

An advantage of the component according to the invention is that the dimensions of the upper contact layer are defined by a limiting structure incorporated into the main body of the component. As a result, the upper contact layer can be manufactured with defined dimensions rather easily.

The electric component according to the invention also features a connecting element which passes through the interior of the main body and connects one of the lower contact layers with the upper contact layer in an electrically conductive manner.

The advantage of the connecting element is that, as a result of its position in the interior of the main body, the feed point of the signal is precisely established in the upper contact layer, so that the electrical properties of the elements are not determined during assembly of the component on the printed circuit board by soldering a contact pin into place.

An advantage of the connecting element also lies in the fact that, by means of SMD assembly, the component can be very easily assembled on a printed circuit board without an additional contact pin. Such assembly can, for example, be accomplished via reflow soldering.

It is especially advantageous to select a ceramic material suitable for microwave resonators as a dielectric. Such a ceramic can, for example, be CaTiO₃—NdAlO₃. Such a ceramic is suitable for use as a microwave resonator at 1575.4 MHz. A component having this ceramic can be used as an antenna for radio signals.

Advantageously, the connecting element passing through the interior of the main body can be formed as a conductive layer, which is applied onto an interior surface of the main body formed by a hole. The hole can, for example, be formed by placement of a bore hole into the main body. This bore hole forms interior surfaces in the main body which can be provided with a conductive layer by precipitation of a metal.

The advantage of this embodiment of the connecting element is that, during the formation of the main body and prior to the application of the contact layers and/or prior to mounting of the component onto a printed circuit board, the feed point for the signal is defined in the upper contact layer by the position of the hole. The feed point is therefore set and does not have to be determined during mounting of the component onto a printed circuit board by relatively convoluted means.

In addition, a component is especially advantageous in which the lower side of the main body features a raised or recessed divider structure. This divider structure divides the lower contact surfaces from one another. With the aid of such a divider structure, the contact layers applied to the lower side of the main body can, in analogy to the upper side of the main body, be suitably dimensioned and insulated from one another. In particular, the dimensioning of the ground surface as a second point of connection for the component can be achieved as a result. The lower contact layers can thus be applied to the lower side of the component in one step and without further structuring processes.

In addition, a component is advantageous in which the upper contact surface is provided with one or more raised or recessed structures to enlarge its surface area. By enlarging the area of the upper contact surface, an enlargement of the electrically active area is also achieved, thereby reducing the geometric dimensions of the electric component. This is especially desirable in light of the ongoing miniaturization of elements, particularly those used in the wireless communications industry.

The remaining structures can take various forms. For example, they can pass along concentric rings or along interlaced squares or rectangles. The remaining structures can be symmetrical to a hole in the main body, although this is not necessary.

Advantageously, the limiting structure on the upper side of the main body can be formed as a recessed structure, i.e., with the upper contact surface being raised relative to the limiting structure. If, furthermore, the upper contact layer is formed via silk screening of a metal paste, the shape of the contact layer determined by the recessed limiting structure can be formed via the silk screen without additional structuring. This is because the recessed limiting structure is not contacted by the metal paste during silk-screening, i.e., only the contact surface that is raised relative to the limiting structure is imprinted. Thus, the shape of the limiting structure may be identical to the shape of the contact layer.

In another advantageous embodiment, the limiting structure is formed as a raised structure. This means that the contact surface is recessed relative to the limiting structure. It is also advantageous when the upper contact layer is a metal coating applied using a precipitation process, since the metal coating can be precipitated onto the entire upper side of the main body, and can subsequently be easily removed from the raised limiting structure by polishing, for example. In this embodiment, the shape of the limiting structure is identical to the shape of the upper contact layer.

The invention also specifies a method for manufacturing a component that comprises the following steps:

(a) Production of a main body that features an upper side with a raised limiting structure.

(b) Precipitation of a contact layer onto the upper side of the main body.

(c) Removal of the contact layer from the raised limiting structure.

The precipitation of the contact layer can be accomplished via precipitation or sputtering, for example. The removal of the contact layer can be performed by polishing.

An advantage of the foregoing method for manufacturing the component is that it allows for a particularly simple and inexpensive method of manufacturing an upper contact layer with defined dimensions.

The invention also specifies a method for manufacturing a component that comprises the following steps:

(a) Production of a main body that features an upper side with a recessed limiting structure.

(b) Application, by means of silk screening, of a contact layer onto the portion of the upper side of the main body that is raised relative to the limiting structure.

An advantage of the method according to the invention is that the contact layer can be applied by simple means and without additional structuring onto only the portion of the upper side of the main body determined by the limiting structure. This is achievable because the silk screening paste used during silk screening does not come into contact with the recessed limiting structure and only adheres to the raised portion of the upper side of the main body.

The specified methods can be designed in a particularly advantageous manner since the limiting structure is created via a pressing-in process during manufacture of the main body. During the course of production of the main body, the ceramic materials used to manufacture the main body are in a ductile state, in which the production of recesses or elevations is easily possible by either pressing in the recess itself or elevating the complementary structure. In particular, limiting structures can be created with a lateral precision of 10 μm via a pressing-in process. Such precision is certainly sufficient for the specified precision levels of the contact surfaces.

In the following, the invention will be explained in greater detail on the basis of exemplary embodiments and the corresponding figures.

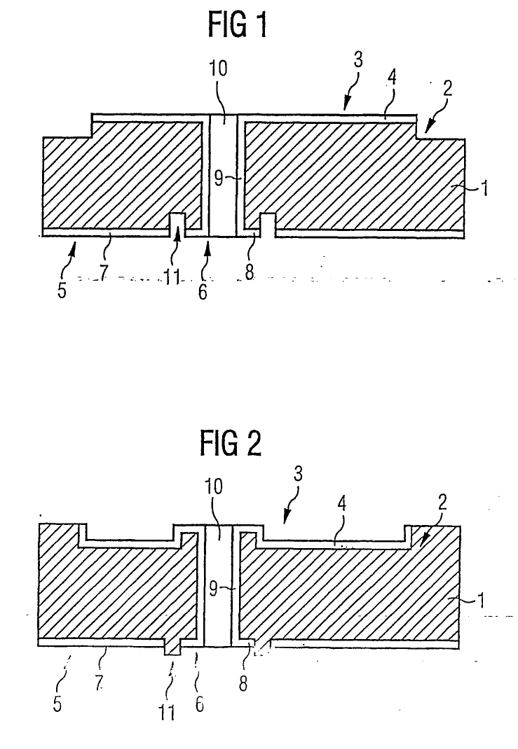

FIG. 1 shows a schematic cross-section of an example of an electric component according to the invention.

FIG. 2 shows a schematic cross-section of an example of another electric component according to the invention.

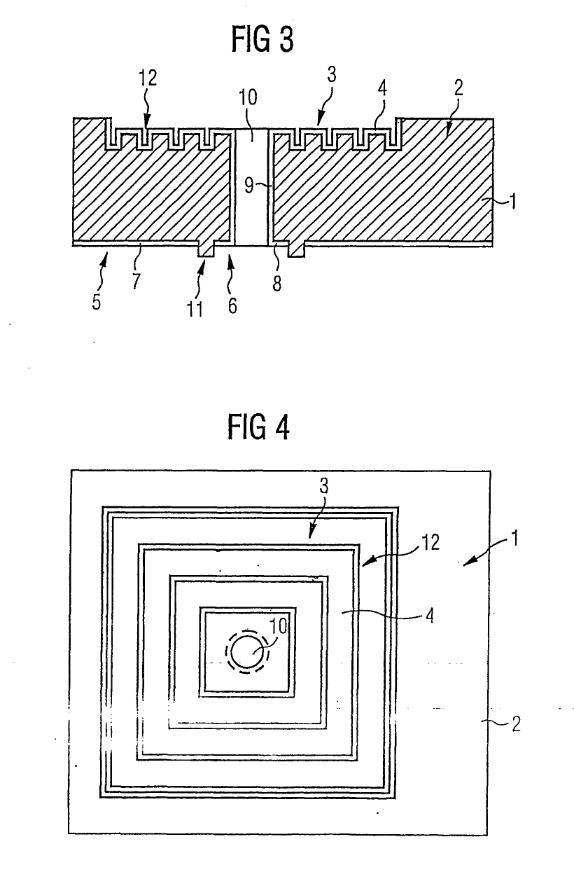

FIG. 3 shows a schematic cross-section of an example of another electric component according to the invention.

FIG. 4 shows the electric component from FIG. 3 in an aerial view.

FIG. 1 shows an electric component with a disk-shaped main body 1. The main body 1 is comprised of CaTiO₃-NdA1O₂. This material has relative permittivity ε of 45. The temperature coefficient of the resonant frequency comprises 0±10 ppm (parts per million) per Kelvin. The resonant frequency itself is 1575 MHz. The main body has a length and width of approximately 18 mm. Its height is approximately 4 mm. The electric component depicted in FIG. 1 may be used as a patch antenna for receipt of GPS (global positioning system) signals.

On its upper side, main body 1 is provided with a recessed limiting structure 2. This limiting structure 2 is formed as a trough. It borders a contact surface 3, which is raised relative to the limiting structure 2. A silver burn-in paste is applied to contact surface 3 via silk screening at a thickness of >5 μm. This burn-in paste forms an upper contact layer 4 on contact surface 3. Radio signals are fed into the antenna through this upper contact layer 4.

A divider structure 11 is provided on the lower side of main body 1. The divider structure is formed as a recessed structure in the shape of a circular groove. The divider structure 11 divides a first lower contact surface 5 in its exterior zone from a second lower contact surface 5 in its interior zone. The advantage of insulating the first lower contact surface 5 from the second lower contact surface 6 via a recessed divider structure 11 is that both contact surfaces 5, 6 can be coated with a first lower contact layer 7 and/or a second lower contact layer 8 via a silk screening process. Without further measures, the two contact layers 7, 8 are electrically insulated from one another. In addition, their geometric shape is firmly established by the shape of the main body 1 and by the shape of the divider structure 11.

In addition, a hole 10 is formed in the main body 1, forming, in the main body 1, an interior surface coated with a metallized coating. This metallized coating comprises a connecting element 9 that connects the second lower contact layer 8 with the upper contact layer 4 in an electrically conductive manner. The connecting element 9 can, for example, be applied onto the interior surface of the main body 1 by sputtering or precipitation.

One advantage of the connecting element 9 is that the component depicted in FIG. 1 can be assembled on a printed circuit board in SMD assembly. In addition to the first lower contact layer 7 (ground contact), the upper contact pad (upper contact layer 4) and the second lower contact layer 8 are electrically connected via the connecting element 9. This eliminates the need for additional connection of the upper contact layer 4 with the printed circuit board via a pin or the like.

FIG. 2 depicts a component, which is substantially similar to the component depicted in FIG. 1. In contrast to FIG. 1, limiting structure 2 of FIG. 2 is formed as a raised structure. Limiting structure 2 forms a collar that runs on the upper side of main body 1 along its outer edge. Similarly, divider structure 11 is formed as a raised structure on the lower side of main body 1. Both upper contact layer 4 and lower contact layers 7, 8 can each be applied by depositing a metal coating, such as by precipitation or sputtering, and can be brought into the desired shape and/or insulated from one another by removal of the metal coating from raised structures 2, 11.

FIG. 3 depicts an electric component that is similar to the component depicted in FIG. 2. In contrast to the component depicted in FIG. 2, the component in FIG. 3 features an additional structure 12, which is formed by troughs disposed within one another and running along square lines. As a result of additional structure 12, the surface of upper contact layer 4, and therefore the effective electric contact surface, is enlarged. It should be noted that the structure height of additional structure 12 is smaller than the structure height of limiting structure 2, as selective removal, by polishing, for example, of a metal coating precipitated or sputtered onto limiting structure 2 would otherwise no longer be possible.

FIG. 4 depicts the component of FIG. 3 in an aerial view. It is evident that the additional structure 12, in the form of square troughs disposed concentrically within one another, is formed on the upper side of the main body 1.

The invention is not limited to the exemplary embodiments depicted, but is instead defined, in its most general form, by claim 1, claim 8, and claim 9.

1. Electric component having a main body (1), which features an upper side and a lower side and consists at least partially of a dielectric,
on the upper side of which a raised or recessed limiting structure (2) borders an upper contact surface (3) which is covered by an upper contact layer (4)
whose lower side features two lower contact surfaces (5, 6) insulated from one another, each of which is covered with a lower contact layer (7, 8), and
in which one of the lower contact layers (5, 6) is connected in electrically conductive fashion to the upper contact layer (4) by a connecting element (9) passing through the interior of the main body (1).

2. Component according to claim 1,
in which the dielectric is a ceramic material suitable for microwave resonators.

3. Component according to claims 1 through 2,
in which the connecting element (9) is a conductive coating which is applied to an interior surface of the main body (1) formed by a hole (10).

4. Component according to claims 1 through 3,
in which the lower side of the main body (1) features a raised or recessed divider structure (11), which divides the lower contact surfaces (5, 6) from one another.

5. Component according to claims 1 through 4,
in which the upper contact surface (3) is provided with one or more additional raised or recessed structures (12) to enlarge its surface area.

6. Component according to claims 1 through 5,
in which the limiting structure (2) is recessed and the upper contact layer (4) is formed by a metal paste applied by silk screening.

7. Component according to claims 1 through 5,
in which the limiting structure (3) is raised and the upper contact layer (4) is a metal coating applied by means of a precipitation process.

8. Method for manufacturing a component according to claims 1 through 7, comprising the following steps:
(a) Production of a main body (1) which features an upper side with a raised limiting structure (2).
(b) Precipitation of a contact layer (4) onto the upper side of the main body (1).
(c) Removal of the contact layer (4) from the raised limiting structure.

9. Method for manufacturing a component according to claims I through 7, comprising the following steps:
(a) Production of a main body (1) which features an upper side with a recessed limiting structure (2).
(b) Application, by means of silk screening, of a contact layer (4) onto the portion of the upper side of the main body (1) which is raised relative to the limiting structure (2).

10. Method according to claim 8 or 9,
wherein the limiting structure (2) is created by means of a pressing-in process during manufacture of the main body (1).

11. Use of the component according to claims 1 to 7 as an antenna for radio signals.
